(19) United States
(12) Patent Application Publication
(10) Pub. No.: US 2013/0161081 A1
(43) Pub. Date: Jun. 27, 2013

(54) CONNECTING STRUCTURE OF TOUCH PANEL

(71) Applicants: Ha Yoon SONG, Gyunggi-do (KR); Young Jae KIM, Gyunggi-do (KR); Seung Min LEE, Gyunggi-do (KR); Ho Joon PARK, Seoul (KR)

(72) Inventors: Ha Yoon SONG, Gyunggi-do (KR); Young Jae KIM, Gyunggi-do (KR); Seung Min LEE, Gyunggi-do (KR); Ho Joon PARK, Seoul (KR)

(73) Assignee: SAMSUNG ELECTRO-MECHANICS CO., LTD., Gyunggi-do (KR)

(21) Appl. No.: 13/427,832

(22) Filed: Mar. 22, 2012

(30) Foreign Application Priority Data
Dec. 26, 2011 (KR) 10-2011-0142571

(51) Int. Cl. H05K 1/11

(52) U.S. Cl. 174/261

(57) ABSTRACT

Disclosed herein is a connecting structure of a touch panel, the connecting structure including a circuit line of a base substrate, a connecting portion having a surface of the circuit line, and a touch signal line connected to the surface of the circuit line and formed on a transparent substrate, wherein the circuit line and the touch signal line are electrically connected to each other by the connecting portion.

### CROSS REFERENCE TO RELATED APPLICATION

This application claims the benefit of Korean Patent Application No. 10-2011-0142571, filed on Dec. 26, 2011, entitled “Connecting Structure of Touch Panel”, which is hereby incorporated by reference in its entirety into this application.

### BACKGROUND OF THE INVENTION

1. Technical Field

The present invention relates to a connecting structure of a touch panel.

2. Description of the Related Art

As computers using digital technologies have been developed, auxiliary devices of computers have been developed together. A personal computer, a portable transmitting device, other personal information processing devices, or the like processes texts and graphics by using various input devices such as keyboards and mouse.

By virtue of rapid development of information-oriented society, the use of a computer has been gradually spread. However, it is difficult to effectively drive a product by simply using a keyboard and a mouse that currently serve as an input device. Thus, there is an increasing need for a device for facilitating simple manipulation, preventing wrong manipulation, and allowing anyone to easily input information.

With regard to technologies related to an input device, attention has been changed from technologies for satisfying requirements for general functions to technologies for high reliability, durability, and innovativeness, technologies related to design and process, and the like. To this end, a touch panel has been developed as an input device facilitating an input of information such as a text, a graphic, or the like.

A touch panel is a tool that is installed on a display surface of a flat display device such as a portable terminal, an electronic notebook, a liquid crystal display device (LCD), a plasma display panel (PDP), an electroluminescence (El), or the like or a display surface of an image display device such as a cathode ray tube (CRT) and is used when a user selects desired information while viewing an image display device.

A touch panel is classified into a resistive-type touch panel, a capacitive-type touch panel, an electromagnetic-type touch panel, a surface acoustic wave (SAW)-type touch panel, and an infrared-type touch panel. These various types of touch panels are used in electronic products in consideration of a signal amplification issue, a difference in resolutions, a difficulty of design and process technologies, optical properties, electrical properties, mechanical properties, environmental properties, input properties, durability, and economic efficiency. In this regard, a touch panel that has been getting the spotlight is a multi-touch capacitive-type touch panel.

Currently, a flexible printed circuit board (FPCB) has been generally used to connect a touch sensor of a touch panel to a printed circuit board (PCB).

However, in order to install an FPCB in a device such as a portable terminal, a quite large space is required and the size of the device is increased. Accordingly, material expenses are increased due to external cases and other components.

Furthermore, other components such as connectors are further required to electrically connect a touch sensor and a PCB to each other through an FPCB, thereby increasing material expenses.

### SUMMARY OF THE INVENTION

The present invention has been made in an effort to provide a connecting structure of a touch panel, which connects a touch signal line of a touch sensor and a circuit line of a base substrate to each other without using a connecting circuit board such as a flexible printed circuit board (FPCB) or the like.

Further, the present invention has been made in an effort to provide a connecting structure of a touch panel, which connects a touch signal line of a touch sensor and a circuit line of a base substrate to each other by using a simple structure.

Further, the present invention has been made in an effort to provide a connecting structure of a touch panel, which fixedly connects a touch signal line of a touch sensor and a circuit line of a base substrate to each other.

According to a preferred embodiment of the present invention, there is provided a connecting structure of a touch panel, the connecting structure including: a circuit line of a base substrate; a connecting portion having a surface connected to the circuit line; and a touch signal line formed on a transparent substrate and connected to the surface of the connecting portion, wherein the circuit line and the touch signal line are electrically connected to each other by the connecting portion.

The connecting portion may include a conductive pad.

The conductive pad may include a support member; and a plurality of conductive rods formed through first and second surfaces of the support member.

The support member may be formed of silicon.

The plurality of conductive rods may each be formed of any one of gold (Au), silver (Ag), and copper (Cu).

The support member may be formed to have a square pillar shape, and the plurality of conductive rods may be formed to each have a cylindrical shape.

The connecting portion may be disposed in a first side portion between the base substrate and the transparent substrate, and an insulating layer may be disposed in a second side portion between the base substrate and the transparent substrate.

The touch signal line may include an electrode wiring.

The base substrate may include a printed circuit board (PCB).

The connecting structure may further include a fixing unit for fixing the connecting portion.

The fixing unit may include a housing having a first side and a second side, wherein the first side may surround the circuit line and the connecting portion and the second side may be fixed to the base substrate by a fixing member.

The fixing member may include a fixing screw.

### BRIEF DESCRIPTION OF THE DRAWINGS

FIG. 1 is an exploded perspective view of a connecting structure of a touch panel according to an embodiment of the present invention;

FIG. 2 is a cross-sectional view of the touch panel taken along a line A-A′ of FIG. 1, according to an embodiment of the present invention;

FIG. 3 is a cross-sectional view of the touch panel taken along a line B-B′ of FIG. 1, according to an embodiment of the present invention;

FIG. 4 is a perspective view of a connecting portion of a connecting structure of a touch panel, according to an embodiment of the present invention; and

FIG. 5 is an exploded perspective view of a connecting portion of a connecting structure of a touch panel, according to an embodiment of the present invention.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings.

In the specification, in adding reference numerals to components throughout the drawings, it is to be noted that like reference numerals designate like components even though components are shown in different drawings.

In addition, the present invention may be modified in various different ways and is not limited to the embodiments provided in the present description. Further, in describing the present invention, a detailed description of related known functions or configurations will be omitted so as not to obscure the subject of the present invention.

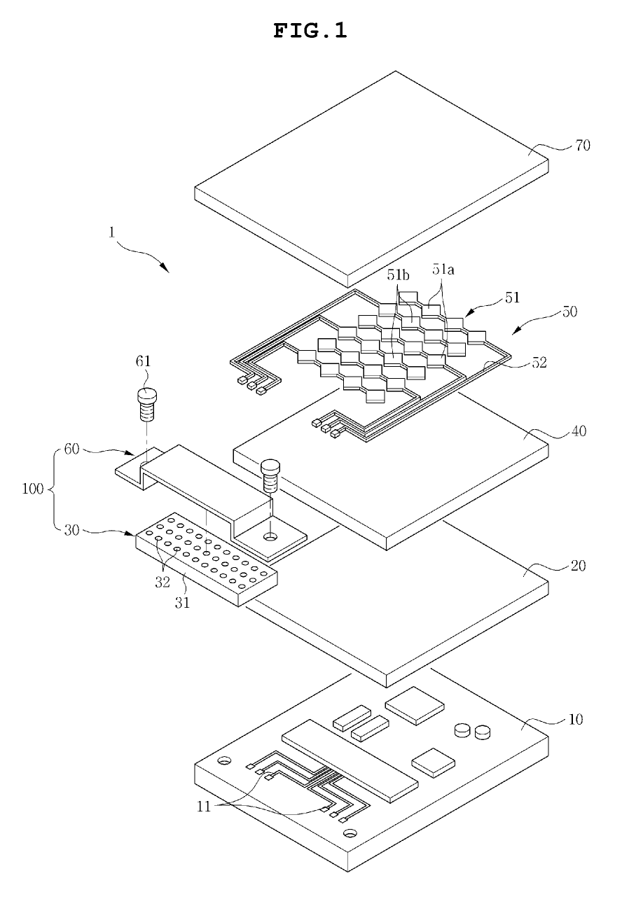

FIG. 1 is an exploded perspective view of a connecting structure 100 of a touch panel 1 according to an embodiment of the present invention.

Referring to FIG. 1, the connecting structure 100 of the touch panel 1 according to the present embodiment includes a circuit line 11 formed on a base substrate 10, a connecting portion 30, and a touch signal line 52 formed on a transparent substrate 70, wherein the circuit line 11 and the touch signal line 52 are electrically connected to each other by the connecting portion 30.

Hereinafter, the connecting structure 100 of the touch panel 1 according to the present embodiment will be described in more detail with reference to FIGS. 1 through 5.

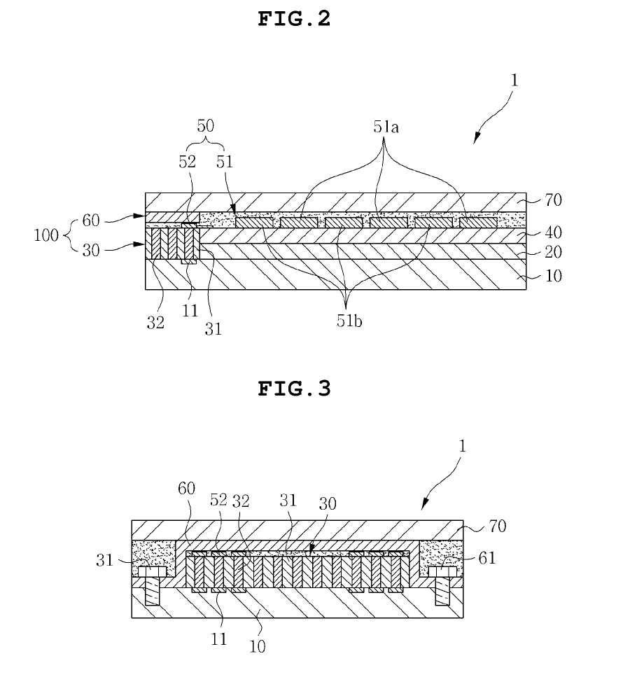

FIG. 2 is a cross-sectional view of the touch panel 1 taken along a line A-A′ of FIG. 1, according to an embodiment of the present invention.

Referring to FIG. 2, the circuit line 11 is formed on a surface of the base substrate 10. In this case, the base substrate 10 may include a printed circuit board (PCB).

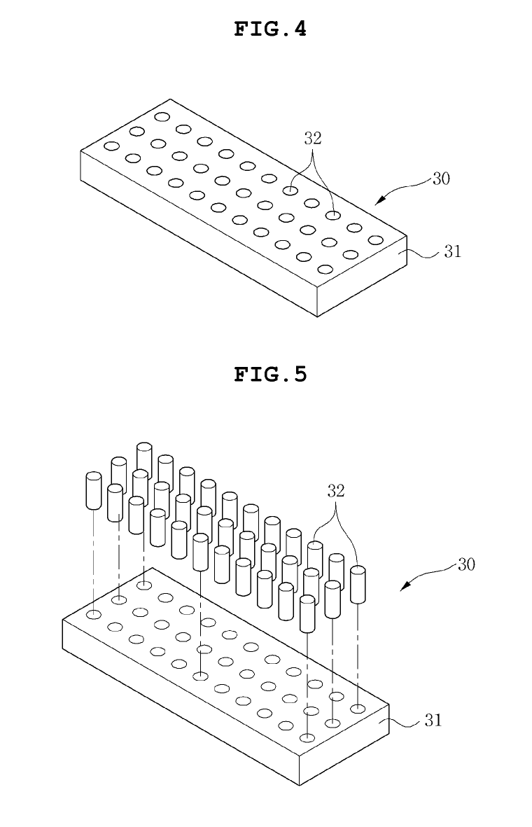

FIG. 4 is a perspective view of the connecting portion 30 of the connecting structure 100 of the touch panel 1, according to an embodiment of the present invention. FIG. 5 is an exploded perspective view of the connecting portion 30 of the connecting structure 100 of the touch panel 1, according to an embodiment of the present invention.

Referring to FIGS. 2 and 4, a first surface of the connecting portion 30 is connected to the touch signal line 52 formed on the transparent substrate 70 and a second surface of the connecting portion 30 is connected to the circuit line 11 formed on the base substrate 10. In this case, for example, the first and second surfaces of the connecting portion 30 may be, but are not limited to, upper and lower surfaces of the connecting portion 30, respectively.

Referring to FIG. 4, the connecting portion 30 may include a conductive pad including a support member 31 and a plurality of conductive rods 32. In this case, the support member 31 may have a square pillar shape having a predetermined thickness and may be formed of silicon.

In addition, referring to FIGS. 4 and 5, the conductive rods 32 are formed through first and second surfaces of the support member 31. In this case, the conductive rods 32 are formed to each have a cylindrical shape and may each be formed of any one of gold (Au), silver (Ag), and copper (Cu).

In this case, referring to FIGS. 2 and 4, for example, the conductive rods 32 may be formed through upper and lower surfaces of the support member 31 in a direction perpendicular to the upper and lower surfaces such that lower surfaces of the conductive rods 32 may be exposed out of the lower surface of the support member 31 and upper surfaces of the conductive rods 32 may be exposed out of the upper surface of the support member 31. In this case, the upper surfaces of the conductive rods 32 may be electrically connected to the circuit line 11 of the base substrate 10 and the lower surfaces of the conductive rods 32 may be electrically connected to the touch signal line 52 formed on the transparent substrate 70.

Referring to FIG. 2, the connecting portion 30 and an insulating layer 40 are disposed in an accommodation space between the base substrate 10 and the transparent substrate 70. In this case, the connecting portion 30 is disposed in a first side portion of the accommodation space and the insulating layer 40 is disposed in a second side portion of the accommodation space.

Referring to FIGS. 1 and 2, the touch signal line 52 is formed on a first surface of the transparent substrate 70, is a line for transmitting a touch signal of a touch sensor 50, and is connected to the first surface of the connecting portion 30.

In this case, the touch sensor 50 may include a touch electrode 51 and the touch signal line 52 connected to the touch electrode 51, wherein the touch signal line 52 may include an electrode wiring.

In addition, the touch signal line 52 transmits a touch signal of the touch electrode 51. In this case, the touch signal line 52 and the touch electrode 51 are formed to be integrated with each other, thereby simplifying manufacturing processes and reducing a lead time.

The transparent substrate 70 may be formed of, for example, any one of tempered glass and a transparent film.

In addition, the touch electrode 51 may include a driving electrode 51a and a sensing electrode 51b.

In this case, when a user touches the touch panel 1, the driving electrode 51a and the sensing electrode 51b may generate a signal such that a controller may recognize a touch coordinate.

The driving electrode 51a or the sensing electrode 51b may be formed of any one of a metal mesh, a conductive polymer, and a metal oxide.

In detail, when the driving electrode 51a or the sensing electrode 51b is formed of a metal mesh, the driving electrode 51a or the sensing electrode 51b may be formed to have a mesh pattern by using a plating process or an evaporation process.

When the driving electrode 51a or the sensing electrode 51b is formed of Cu, a blackening process may be performed on a surface of the driving electrode 51a or a surface of the sensing electrode 51b. In this case, in the blackening process, the surface of the driving electrode 51a or the surface of the sensing electrode 51b is oxidized to precipitate Cu₂O or CuO. In this case, since Cu₂O exhibits brown color, Cu₂O is referred to as a brown oxide. Since CuO exhibits black color, CuO is referred to as a black oxide.

Thus, by performing the blackening process on the surface of the driving electrode 51a or the surface of the sensing electrode 51b, light may be prevented from being reflected off the surface of the driving electrode 51a or the surface of the sensing electrode 51b, thereby improving the visibility of the touch panel 1.

In addition, when the driving electrode 51a or the sensing electrode 51b is formed to have a mesh pattern, a line width of the driving electrode 51a or the sensing electrode 51b may be equal to or less than 7 μm and a pitch of the driving electrode 51a or the sensing electrode 51b may be equal to or less than 900 μm, thereby improving the visibility of the touch panel 1. However, the line with and the pitch of the driving electrode 51a or the sensing electrode 51b are not limited to these ranges.

In addition to the above-described metals, the driving electrode 51a or the sensing electrode 51b may be formed metallic silver obtained by exposing/developing a silver salt emulsion layer.

In addition, a conductive polymer has high flexibility and makes a coating process easier. In this case, the conductive polymer may include poly-3,4-ethylenedioxythiophene/polystyrenesulfonate (PEDOT/PSS), polyaniline, polyacetylene, or polyphenylenevinylene.

In addition, the metal oxide includes indium-tin oxide (ITO).

In this case, the driving electrode 51a or the sensing electrode 51b is formed of a conductive polymer or a metal oxide by using a dry process, a wet process, or a direct patterning process. Examples of the dry process include sputtering, evaporation, and the like. Examples of the wet process include dip coating, spin coating, roll coating, and spray coating. Examples of the direct patterning process include screen printing, gravure printing, and inkjet printing.

In addition, referring to FIG. 2, for example, an upper surface of the touch sensor 50 may contact a lower surface of the transparent substrate 70, a first side of a lower surface of the touch sensor 50 may contact the upper surface of the connecting portion 30, and a second side of the lower surface of the touch sensor 50 may contact an upper surface of the insulating layer 40. In this case, the touch signal line 52 of the touch sensor 50 may be disposed on a first side of the lower surface of the transparent substrate 70 and the touch electrode 51 may be disposed on a second side of the lower surface of the transparent substrate 70.

In addition, the insulating layer 40 may be formed as a film In this case, the insulating layer 40 may be formed of, but is not limited to, any one of polyethyleneterephthalate (PET), polycarbonate (PC), polymethyl methacrylate (PMMA), polyethylenenaphthalate (PEN), polyethersulfone (PES), cyclic olefin copolymer (COC), triacetylcellulose (TAC), polyvinyl alcohol (PVA), polyimide (PI), polystyrene (PS), and K resin-containing biaxially oriented polystyrene (BOPS). Alternatively, the insulating layer 40 may be formed of, for example, silicon dioxide or the like.

In order to activate two surfaces of the insulating layer 40, high-frequency treatment or primer treatment may be performed on the two surfaces of the insulating layer 40. By activating the two surfaces of the insulating layer 40, adhesion between the touch electrode 51 and the insulating layer 40 may be increased.

Referring to FIG. 2, a display 20 for displaying an image may be disposed between the insulating layer 40 and the base substrate 10.

FIG. 3 is a cross-sectional view of the touch panel 1 taken along a line B-B′ of FIG. 1, according to an embodiment of the present invention.

Referring to FIGS. 1 and 3, the connecting structure 100 of the touch panel 1 according to the present embodiment may further include a fixing unit for fixing the connecting portion 30.

In this case, the fixing unit may include a housing 60. A first side of the housing 60 surrounds the circuit line 11 and the connecting portion 30 and a second side of the housing 60 is fixed to the base substrate 10 by fixing members 61.

The fixing members 61 may each include a fixing screw.

According to the present invention, a touch signal line of a touch sensor and a circuit line of a base substrate may be connected to each other without using a connecting circuit board such as a flexible printed circuit board (FPCB) or the like, thereby ensuring a maximum internal space of a touch device.

In addition, the touch signal line of the touch sensor and the circuit line of the base substrate may be connected to each other by using a simple structure, thereby making a connecting process easier and reducing a manufacturing time.

Further, since the touch signal line of the touch sensor and the circuit line of the base substrate may be fixedly connected to each other, thereby preventing the touch signal line and the circuit line from being disconnected from each other.

Although the preferred embodiments of the present invention have been disclosed for illustrative purposes, they are for specifically explaining the present invention. Therefore, a connecting structure of a touch panel according to the preferred embodiments of the present invention is not limited thereto, but those skilled in the art will appreciate that various modifications and alteration are possible, without departing from the scope and spirit of the invention as disclosed in the accompanying claims.

Accordingly, such modifications and alterations should also be understood to fall within the scope of the present invention. A specific protective scope of the present invention could be defined by accompanying claims

What is claimed is:

1. A connecting structure of a touch panel, the connecting structure comprising:
a circuit line formed on a surface of a base substrate;
a connecting portion having a surface connected to the circuit line; and
a touch signal line connected to a surface of the connecting portion and formed on a surface of a transparent substrate,
wherein the circuit line and the touch signal line are electrically connected to each other by the connecting portion.

2. The connecting structure as set forth in claim 1, wherein the connecting portion includes a conductive pad.

3. The connecting structure as set forth in claim 2, wherein the conductive pad includes:
a support member; and
a plurality of conductive rods formed through first and second surfaces of the support member.

4. The connecting structure as set forth in claim 3, wherein the support member is formed of silicon.

5. The connecting structure as set forth in claim 3, wherein the plurality of conductive rods are each formed of any one of gold (Au), silver (Ag), and copper (Cu).

6. The connecting structure as set forth in claim 3, wherein the support member is formed to have a square pillar shape, and
wherein the plurality of conductive rods are formed to each have a cylindrical shape.

7. The connecting structure as set forth in claim 1, wherein the connecting portion is disposed in a first side portion between the base substrate and the transparent substrate, and
wherein an insulating layer is disposed in a second side portion between the base substrate and the transparent substrate.

8. The connecting structure as set forth in claim 1, wherein the touch signal line includes an electrode wiring.

9. The connecting structure as set forth in claim 1, wherein the base substrate includes a printed circuit board (PCB).

10. The connecting structure as set forth in claim 1, further comprising a fixing unit fixing the connecting portion.

11. The connecting structure as set forth in claim 10, wherein the fixing unit includes a housing having a first side and a second side, wherein the first side surrounds the circuit line and the connecting portion and the second side is fixed to the base substrate by a fixing member.

12. The connecting structure as set forth in claim 11, wherein the fixing member includes a fixing screw.
